(19) United States
(12) Patent Application Publication
(10) Pub. No.: US 2026/0215273 A1
(43) Pub. Date: Jul. 23, 2026

(54) POWER SEMICONDUCTOR MODULE

(71) Applicants: Dynex Semiconductor Limited, Lincoln (GB); Zhuzhou CRRC Times Semiconductor Co. Ltd, Zhuzhou, Hunan (CN)

(72) Inventors: Robin Adam SIMPSON, Lincoln (GB); Michael David NICHOLSON, Lincoln (GB)

(21) Appl. No.: 19/141,764

(22) PCT Filed: Dec. 22, 2022
(86) PCT No.: PCT/EP2022/087501

§ 371 Date: Jun. 20, 2025

(51) Int. Cl. H10W 40/47; H10W 40/25; H10W 40/60; H10W 42/20; H10W 70/40; H10W 90/10

(52) U.S. Cl. CPC H10W 40/475; H10W 40/255; H10W 42/267; H10W 70/411; H10W 70/479; H10W 70/481; H10W 90/10; H10W 40/611

(57) ABSTRACT

There is provided a power semiconductor module, comprising: a switching circuit 1000 comprising high-side and low-side power semiconductor devices 1100, 1200, and a switching node AC between the high-side and low-side power semiconductor devices; and a substrate 50 comprising: an electrically insulating body 5; a first electrically conductive layer arranged on a first surface of the electrically insulating body that faces the switching circuit; and a second electrically conductive layer arranged on a second opposite surface of the electrically insulating body. The first electrically conductive layer comprises a first conductive track 4 electrically connected to the switching node AC, and the second electrically conductive layer comprises a second conductive track 16 for coupling to a heat removal structure 9. The first conductive track 4 does not overlap with the second conductive track 16 across the electrically insulating body 5.

### TECHNICAL FIELD

This disclosure relates to a power semiconductor module and a method of manufacturing the same. More particularly, but not exclusively, this disclosure relates to a power semiconductor module with optimised parasitic capacitances to minimise electromagnetic interference (EMI).

### BACKGROUND

It is known that parasitic capacitances in power semiconductor modules interact with high voltage transients to produce displacement currents. By way of an example, FIG. 1 schematically illustrates a half-bridge circuit structure 1000 with parasitic capacitances. The half-bridge circuit structure 1000 includes a high-side power switch 1100 and a low-side power switch 1200 connected in series between a DC+ node and a DC− node. The half-bridge structure also has a switching node AC connected between the high-side power switch 1100 and the low-side power switch 1200. There is a parasitic capacitance C_{AC} between the switching node AC and a ground node GND. There is also a parasitic capacitance C_{DC+} between the DC+ node and the ground node GND, and a parasitic capacitance C_{DC-} between the DC− node and GND.

FIG. 4 shows part of a conventional power semiconductor assembly 100, and the physical locations of the parasitic capacitances C_{AC}, C_{DC+}, C_{DC-} in the assembly 100. The power semiconductor assembly 100 includes a conventional power semiconductor module realising the half-bridge circuit structure 1000 and a cooling system.

The conventional power semiconductor module has a copper-clad ceramic substrate 150 (shown in FIGS. 2 and 3) and power semiconductor devices (not shown) mounted on the substrate 150. The DC+, DC− and AC nodes of the half-bridge circuit structure 1000 are connected to conductive tracks 102, 103, 104 formed on an upper copper layer of the substrate 150 (FIG. 2). A lower copper layer 106 of the substrate 150, separated from the upper copper layer by a ceramic layer 105, is not patterned and covers continuously over almost the entire area of the bottom surface of the ceramic layer 105.

The cooling system includes a baseplate 107 with integrated cooling fins 108 bonded to the lower copper layer 106, and a cooling bath 109 further mounted to a peripheral region of the baseplate 107 using mounting screws 112, thereby forming a coolant reservoir 111 between the cooling bath 109 and the baseplate 107. A sealing gasket 110 is used to prevent escape of fluid from the coolant reservoir 11.

In use, the cooling bath 109 is typically connected to ground 20. Since the cooling path 109 and the baseplate 107 are typically made of electrically conductive materials (e.g., metal), the lower copper layer 106 is also electrically connected to ground 20. Therefore, the capacitance 115 between the conductive track 104 and the lower copper layer 106 across the ceramic layer 105 is the parasitic capacitance C_{AC}. The capacitance 113 between the conductive track 102 and the lower copper layer 106 is the parasitic capacitance C_{DC+}, and the capacitance 114 between the conductive track 103 and the lower copper layer 106 is the parasitic capacitance C_{DC-}.

During operation of the conventional power semiconductor module, the parasitic capacitance C_{AC} is charged and discharged in every switching cycle. The displacement current is the product of the capacitance and the rate of change of voltage (dv/dt). During turn-on of the low side switch 1200, the displacement current flows through the low side switch 1200, increasing switching losses (D.N. Dalal et al., “Impact of Power Module Parasitic Capacitances on Medium-Voltage SiC MOSFETs Switching Transients”, IEEE Journal of Emerging and Selected Topics in Power Electronics, vol. 8, no. 1, pp. 298-310, March 2020, doi: 10.1109/JESTPE.2019.2939644). The displacement current also causes common mode noise in the ground circuit, which is a cause of EMI (Siemens, “Experimental and Simulative Investigations of Conducted EMI Performance of IGBTs for 5-10 KVA Converters”).

The interaction between high voltage transients and C_{DC+}, C_{DC-} can lead to differential mode noise. This occurs when C_{DC+}, C_{DC-} are imbalanced (G. Regnat, et al., “Optimized power modules for silicon carbide MOSFET”, 2016 IEEE Energy Conversion Congress and Exposition (ECCE), 2016, pp. 1-8, doi: 10.1109/ECCE.2016.7855324).

These problems have been present in silicon-based power modules using IGBT chips as the switches 1100, 1200 for the past few decades, but the resulting increases in switching losses and EMI have not been significant enough to warrant targeted steps during module design. Any non-compliance with regulations governing EMI has typically been managed by means outside the power module, such as filter circuitry for conducted emissions and physical shielding for radiated emissions. With the transition to the use of wide bandgap (WBG) power semiconductor devices (including gallium nitride and silicon carbide) as the switches 1100, 1200, dv/dt during switching events is increased significantly, meaning that displacement currents are now of a magnitude requiring consideration during module design.

While the problems are described above with respect to a power semiconductor module realising a half-bridge circuit structure 1000, it would be appreciated that the problems affect power modules realising any type of switching circuits which are not limited to the half-bridge circuit structure.

To reduce the magnitude of the displacement currents in power semiconductor modules, D. N. Dalal et al. (“Impact of Power Module Parasitic Capacitances on Medium-Voltage SIC MOSFETs Switching Transients”, IEEE Journal of Emerging and Selected Topics in Power Electronics, vol. 8, no. 1, pp. 298-310, March 2020, doi: 10.1109/JESTPE.2019.2939644) demonstrates that reducing the area of the substrate pads at AC potential (e.g., the track 104 of FIG. 4) can reduce the displacement currents caused by C_{AC} during switching events. The capacitance CAc is proportional to the area of overlap between the AC pad and the grounded pad, so it follows that the reduction in displacement current is proportional to the reduction in area. However, there is a lower limit to this, since the area of substrate pads cannot be reduced below the footprint of the components (e.g. chips, interconnections and module terminals) attached to these pads.

In WO2007/078285A1, an additional insulation layer is added between a lower conductive layer of a substrate and a baseplate. The purpose of the additional insulation layer is to reduce the capacitance between an upper conductive layer of the substrate and the baseplate, thereby reducing the magnitude of the displacement currents for a given dv/dt. However, this is achieved at the expense of higher thermal resistance, since a new layer of material is introduced into the cooling path between the substrate and the baseplate.

In U.S. Pat. No. 10,032,732B1, the concept from WO2007/078285A1 is developed a step further. A second substrate is attached to the underside of a first substrate. The addition of the second substrate also increases the thermal resistance of a cooling path between the first substrate and a baseplate.

In US2021/100128A1, capacitive coupling between regions of AC potential and ground is reduced through the use of a substrate with integrated vias connecting defined areas of an upper conductive layer to a lower conductive layer of the substrate, enabling the creation of a vertical current loop. The substrate is mounted on an electrically insulating baseplate/cooling structure, which isolates a DC− pad from ground. As for previous techniques, this approach would likely lead to increased thermal resistance, since a baseplate/cooling structure manufactured from ceramic or another electrically insulating material will have a significantly lower thermal conductivity than a typical metal-based baseplate.

It is an object of the present disclosure, among others, to provide an improved power semiconductor module that solves problems associated with conventional power semiconductor modules, whether identified herein or otherwise.

### SUMMARY

According to a first aspect of this disclosure there is provided a power semiconductor module, comprising: a switching circuit comprising high-side and low-side power semiconductor devices, and a switching node between the high-side and low-side power semiconductor devices; and a substrate comprising: an electrically insulating body; a first electrically conductive layer arranged on a first surface of the electrically insulating body that faces the switching circuit; and a second electrically conductive layer arranged on a second opposite surface of the electrically insulating body; wherein the first electrically conductive layer comprises a first conductive track electrically connected to the switching node, and the second electrically conductive layer comprises a second conductive track for coupling to a heat removal structure, and wherein the first conductive track does not overlap with the second conductive track across the electrically insulating body.

Advantageously, by making the first conductive track not overlap with the second conductive track across the electrically insulating body, the capacitive coupling between the switching node of the switching circuit and ground (to which the heat removal structure is typically connected in use) can be significantly reduced without increasing the thermal resistance of the power semiconductor module. Reducing the capacitive coupling is useful for reducing displacement currents of the switching circuit and thus useful for reducing the switching loss of the power semiconductor module. It is also useful for reducing common node noise in the ground circuit which is a cause of EMI.

Within the present disclosure, the term “electrically connected” describes a permanent low-ohmic connection between electrically connected elements, for example a direct contact between the concerned elements or a low-ohmic connection via metal conductor(s).

The term “coupled” or “coupling” used in the present disclosure includes that one or more intervening element(s) may exist between the coupled elements.

The term “overlap” used in the present disclosure means that when the substrate is viewed along a direction perpendicular to the first/second surface of the electrically insulating body, and relevant conductive tracks are projected onto a same two-dimensional plane which is parallel to the first/second surface of the electrically insulating body, the projections of the relevant conductive tracks cover some common area.

The second electrically conductive layer may be electrically insulated from the first electrically conductive layer. The heat removal structure may comprise a coolant casing.

The second conductive track may be loop-shaped.

The second conductive track may assume a loop shape that is rectangular, oval, annular, square, polygonal or non-geometrical, etc., as long as it forms a closed loop that is without a gap.

The first electrically conductive layer may further comprise third and fourth conductive tracks which are electrically connected a DC positive node and a DC negative node of the switching circuit. Each of the third and fourth conductive tracks may overlap with the second conductive track across the electrically insulating body.

An overlapping area between the third and second conductive tracks across the electrically insulating body has a substantially identical size to an overlapping area between the fourth and second conductive tracks across the electrically insulating body.

The term “substantially identical” means that the size of one overlapping area is within a range of between 80% and 120% of the size of another overlapping area.

Advantageously, this arrangement is useful for balancing parasitic capacitances from the DC+ node to ground and from the DC− node to ground. Balanced capacitances to ground minimise differential currents that are a cause of EMI.

The second electrically conductive layer may further comprise a fifth conductive track for coupling to a heat exchanger. The fifth conductive track may be surrounded by and spaced apart from the second conductive track.

The fifth conductive track is therefore electrically insulated from the second conductive track (and also from the heat removal structure coupled to the second conductive track). The heat exchanger may comprise cooling fins.

The first conductive track may overlap with the fifth conductive track across the electrically insulating body.

Alternatively, the second electrically conductive layer may further comprise sixth to eighth conductive tracks for coupling to a plurality of heat exchangers. The sixth to eighth conductive tracks may be surrounded by the second conductive track, the sixth to eighth conductive tracks being spaced apart from the second conductive track and also spaced apart from one another. The sixth conductive track may overlap with only the first conductive track of the first electrically conductive layer across the electrically insulating body. The seventh conductive track may overlap with only the third conductive track of the first electrically conductive layer across the electrically insulating body. The eighth conductive track may overlap with only the fourth conductive track of the first electrically conductive layer across the electrically insulating body.

Advantageously, the arrangement of the sixth to eighth conductive tracks reduce crosstalk between the first, third and fourth conductive tracks which are of different potentials during operation of the switching circuit.

At least one of the high-side and low-side power semiconductor devices may comprise a wide bandgap power semiconductor device.

According to a second aspect of this disclosure, there is provided a power semiconductor assembly, comprising: the power semiconductor module of the first aspect; and a coolant casing for containing coolant, wherein the coolant casing is coupled to the second conductive track so that the second conductive track shares a voltage potential of the coolant casing, and wherein the heat removal structure comprises the coolant casing.

More specifically, the coolant casing may be mechanically and electrically coupled to the second conductive track. The coolant casing may be typically connected to ground in use. The coolant casing may comprise a coolant inlet and a coolant output.

The power semiconductor assembly may further comprise a baseplate bonded between the second conductive track and the coolant casing.

Alternatively, the coolant casing may be directly bonded to the second conductive track.

With the expression “directly bonded”, it is meant that no other structure is between the baseplate/casing and the second conductive track (except a small amount of bonding material used).

By directly bonding the coolant casing to the second conductive track, the footprint of the power semiconductor assembly can be reduced. The total costs of the power semiconductor assembly is also used due to reductions of components manufacturing steps. Further, sealing integrity of coolant is improved as there is no reliance on a sealing gasket.

The power semiconductor assembly may further comprise a coolant contained in the coolant casing, wherein the coolant is thermally coupled to the electrically insulating body.

Within the present disclosure, the term “thermally coupled” includes that one or more intervening element(s) may exist between the thermally coupled elements. the coolant may be dielectric.

The coolant may contact the second surface of the electrically insulating body directly. In other words, there may be no conductive track surrounded by the second conductive track within the second electrically conductive layer.

An internal surface of the coolant casing may comprise a structure for guiding the coolant. Advantageously, the structure is useful for improving cooling of the substrate. The coolant casing may be part of a jet impingement cooling system which is configured to direct jets of coolants onto the substrate.

The power semiconductor assembly may comprise the jet impingement cooling system.

The power semiconductor assembly may further comprise a heat exchanger bonded to the fifth conductive track, wherein the heat exchanger is electrically insulated from the second conductive track.

Alternatively, the power semiconductor assembly may comprise a plurality of heat exchangers, each of which is bonded to a respective one of the sixth to eighth conductive tracks and is electrically insulated from the second conductive track.

Therefore, the heat exchangers would not couple different ones of the sixth to eighth conductive tracks, thereby reducing crosstalk between the first, third and fourth conductive tracks. The use of the plurality of heat exchangers (as compared to a single heat exchanger) is advantageous in that the heat exchangers can be concentrated in areas with the greatest heat flux, potentially reducing material usage and costs.

Further, each of the heat exchangers would have a smaller area, which enables a wider range of bonding processes.

According to a third aspect of this disclosure, there is provided a method of manufacturing a power semiconductor module, the power semiconductor module having a switching circuit comprising: high-side and low-side power semiconductor devices, and a switching node between the high-side and low-side power semiconductor devices, the method comprising:
providing a substrate which comprises: an electrically insulating body; a first electrically conductive layer arranged on a first surface of the electrically insulating body that faces the switching circuit; and a second electrically conductive layer arranged on a second opposite surface of the electrically insulating body, wherein the first electrically conductive layer comprises a first conductive track and the second electrically conductive layer comprises a second conductive track for coupling to a heat removal structure; and
electrically connecting the first conductive track to the switching node of the switching circuit;
wherein the first conductive track does not overlap with the second conductive track across the electrically insulating body.

According to a fourth aspect of this disclosure, there is provided a method of manufacturing a power semiconductor assembly, comprising: the method of the third aspect; and coupling a heat removal structure to the second conductive track.

It would be understood that the terms “first” to “eighth ”are simply used in the present disclosure to label the relevant elements (e.g., “conductive track”, “electrically conductive layer” etc.) for the ease of description, and do not imply any limitations to the sequence, locations or total number of the relevant elements.

Where appropriate any of the optional features described above in relation to one of the aspects of the disclosure may be applied to another one of the aspects of the disclosure.

### BRIEF DESCRIPTION OF THE DRAWINGS

In order that the disclosure may be more fully understood, a number of embodiments of the disclosure will now be described, by way of example, with reference to the accompanying drawings, in which:

FIG. 1 schematically illustrates a circuit diagram of a half-bridge circuit structure with parasitic capacitances;

FIG. 2 is a schematic representation of a top plan view of a substrate used in a conventional power semiconductor module that realises the half-bridge circuit structure of FIG. 1;

FIG. 3 is a schematic representation of a bottom plan view of the substrate of FIG. 2;

FIG. 4 is a schematic representation of a, partial, cross-sectional view of a power semiconductor assembly that is based upon the conventional power semiconductor module when the substrate is cut along line IV-IV′ in FIG. 2;

FIG. 5 is a schematic representation of a top plan view of a substrate used in a power semiconductor module according to an embodiment of the present disclosure;

FIG. 6 is a schematic representation of a bottom plan view of the substrate of FIG. 5;

FIG. 7 conceptually illustrates an overlap between top and bottom electrically conductive layers of the substrate of FIGS. 5 and 6;

FIG. 8 is a schematic representation of a, partial, cross-sectional view of a power semiconductor assembly according to a first embodiment of the present disclosure when the substrate is cut along line VIII-VIII′ in FIG. 7;

FIG. 9 a schematic representation of a, partial, cross-sectional view of a power semiconductor assembly according to a second embodiment of the present disclosure;

FIG. 10 a schematic representation of a, partial, cross-sectional view of a power semiconductor assembly according to a third embodiment of the present disclosure;

FIG. 11 a schematic representation of a, partial, cross-sectional view of a power semiconductor assembly according to a fourth embodiment of the present disclosure;

FIG. 12 a schematic representation of a, partial, cross-sectional view of a power semiconductor assembly according to a fifth embodiment of the present disclosure;

FIG. 13 a schematic representation of a, partial, cross-sectional view of a power semiconductor assembly according to a sixth embodiment of the present disclosure;

FIG. 14 schematically illustrates processing steps of a method for manufacturing a power semiconductor module according to the present disclosure.

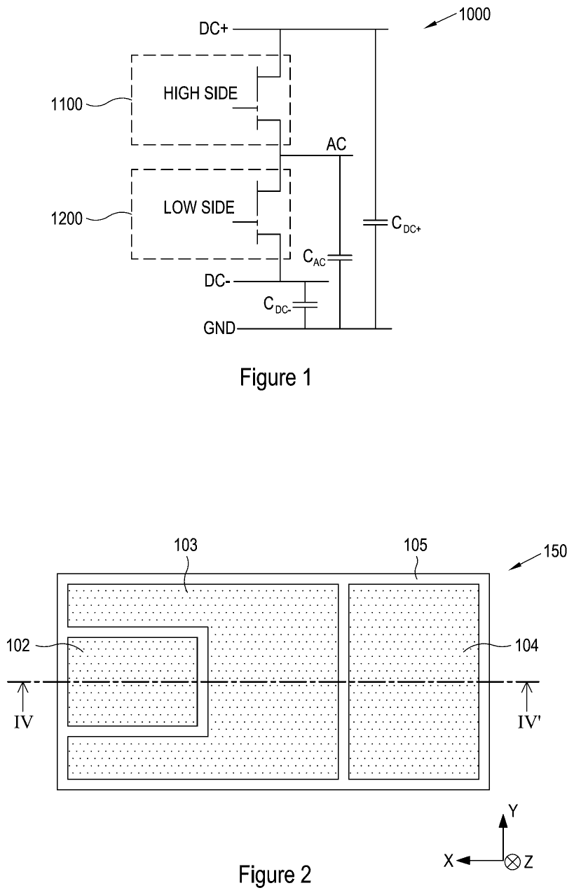

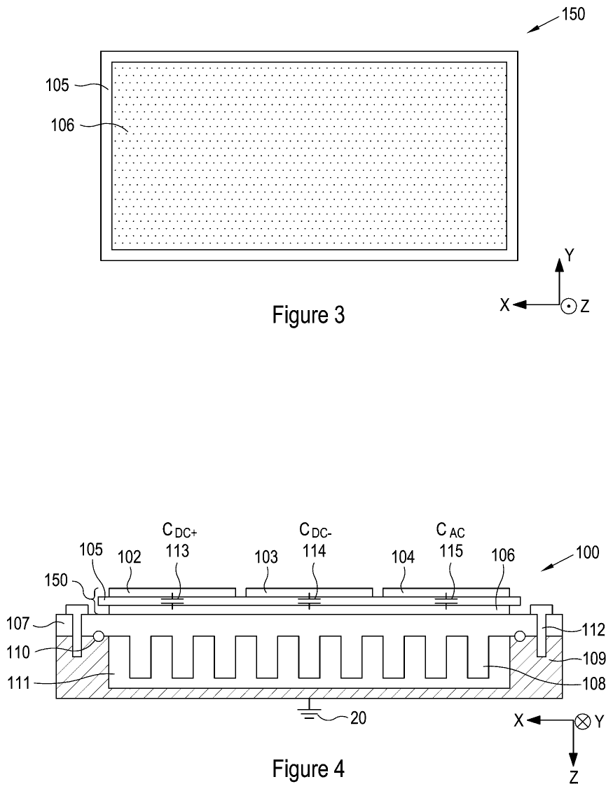

In the figures, like parts are denoted by like reference numerals.

It will be appreciated that the drawings are for illustration purposes only and are not drawn to scale.

### DETAILED DESCRIPTION OF THE PREFERRED EMBODIMENTS

FIG. 8 schematically illustrates part of a cross-sectional view of a power semiconductor assembly 1 (hereinafter, “assembly 1”) according to a first embodiment of the present disclosure. The assembly 1 includes a power semiconductor module according to the present disclosure that realises the half-bridge circuit structure 1000, and a cooling system for use with the power semiconductor module.

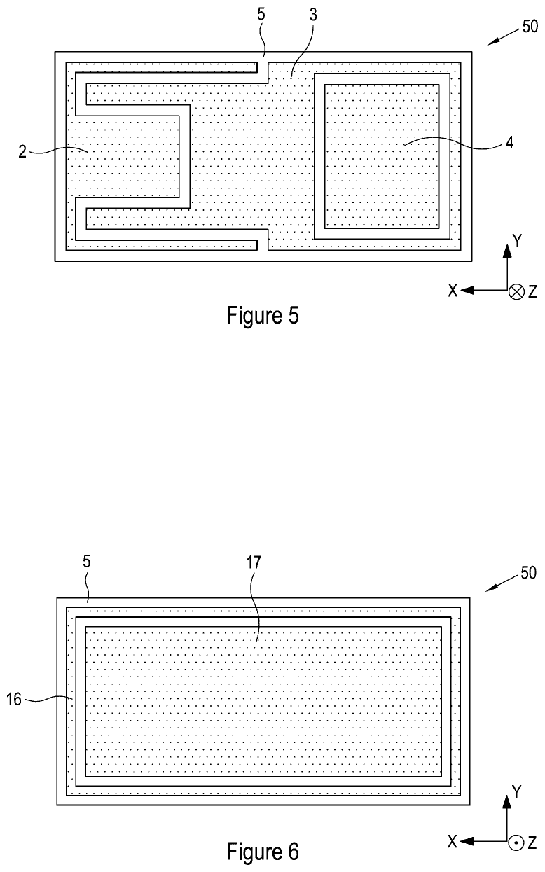

The power semiconductor module of the assembly 1 has a substrate 50 (also shown in FIGS. 5 to 7) and power semiconductor devices (not shown) mounted on the substrate 50.

The substrate 50 of the power semiconductor module has an electrically insulating body 5, a top patterned electrically conductive layer arranged on a top surface of the electrically insulating body 5, and a bottom patterned electrically conductive layer arranged on a bottom surface of the electrically insulating body 5. The electrically insulating body 5 is typically made of ceramic or a suitable polymer. The top and bottom patterned electrically conductive layers may be made of copper or other suitable conducting material such aluminum, copper-molybdenum alloy, or copper-tungsten alloy etc. The bottom electrically conductive layer is electrically insulated from the top electrically conductive layer. The substrate 50 may be a direct bonded copper (DBC) substrate, a direct bonded aluminium (DBA) substrate or an active metal brazed (AMB) substrate. The top and bottom patterned electrically conductive layers may also be referred to as “a first electrically conductive layer” and “a second electrically conductive layer”, respectively.

The top patterned electrically conductive layer of the substrate 50 is shown in more detail in FIG. 5. More specifically, the top patterned electrically conductive layer is divided into conductive tracks 2, 3, 4 which are spaced apart from one another (hence electrically insulated from one another if further electrical connections were not provided). The conductive track 3 surrounds the conductive track 4, and interleaves with the conductive track 2. The conductive tracks 2, 3, 4 are electrically connected to the DC+, DC− and AC nodes of the half-bridge circuit structure 1000, respectively. Therefore, the conductive tracks 2, 3, 4 may also be referred to as DC+ pad, DC− pad and AC pad, respectively. As described above, the AC node is a switching node of the half-bridge circuit structure 1000.

While the figures do not show the high-side and low-side power switches 1100, 1200 or their connections to the conductive tracks 2, 3, 4, it would be understood that they can be realised using any suitable way. For example, each of the high-side and low-side power switches 1100, 1200 may include any suitable numbers of power semiconductor device(s) electrically connected in parallel to one another depending upon the required rating of the half-bridge circuit 1000. The power semiconductor device(s) may comprise a WBG power transistor (e.g., GaN HEMTs) or a silicon-based power transistor (e.g., IGBT, MOSFET, IEGT, BJT, IGCT, GTO etc.). Further, one or more of the high-side and low-side power switches 1100, 1200 may further include a power diode (such as a fast recovery diode or a Schottky diode) in anti-parallel connections with the power transistor(s) therein. The power semiconductor devices may be lateral devices or vertical devices. Power electrodes of the power semiconductor devices may be electrically connected to the conductive tracks 2, 3, 4 by direct bonding (e.g., soldering or sintering), wire bonds, copper clips, and/or a flexible circuit board, etc..

The bottom patterned electrically conductive layer of the substrate 50 is shown in more detail in FIG. 6. More specifically, the bottom patterned electrically conductive layer is divided into conductive tracks 16, 17 which are spaced apart from one another (hence electrically insulated from one another if further electrical connections were not provided). The conductive track 16 is loop-shaped and surrounds the large-area central conductive track 17.

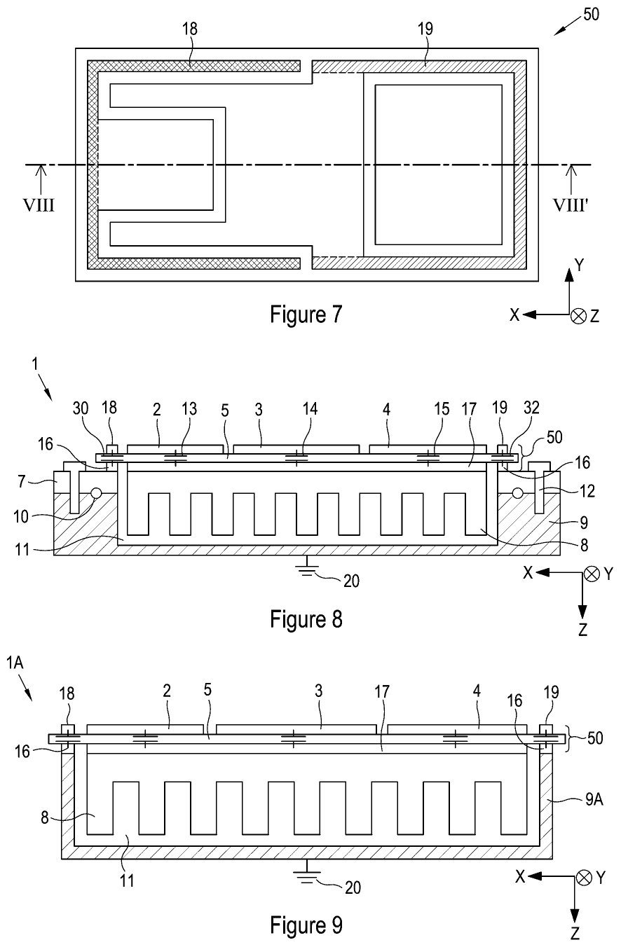

FIG. 7 conceptually illustrates an overlap between the top and bottom electrically conductive layers of the substrate 50. FIG. 7 is generated when the substrate 50 is viewed along a vertical Z direction perpendicular to the top/bottom surface (along an X-Y plane) of the electrically insulating body 5, with the electrically insulating body 5 being transparent. As shown in FIG. 7, the DC+ pad 2 has an overlapping region 18 with the conductive track 16, and the DC− pad 3 has an overlapping region 19 with the conductive track 16. Due to the looped-shape design of the conductive track 16, the overlapping region 18 or 19 merely takes up a small percentage of the area of the DC+ pad 2 or the DC− pad 3. The AC pad 4 overlaps with the conductive track 17, but does not overlap with the conductive track 16.

The cooling system of the assembly 1 includes a baseplate 7, a heat exchanger 8, a coolant casing 9 for containing coolant, a sealing gasket 10, a coolant reservoir 11, and mounting screws 12.

To assemble the module with the cooling system, the heat exchanger 8 (which is embodied as cooling fins in FIG. 8) are bonded to the central conductive track 17 of the bottom patterned electrically conductive layer. The loop-shaped baseplate 7 is then bonded to the thin surrounding conductive track 16 of the bottom patterned electrically conductive layer, as shown in FIG. 8. The bonding processes may be performed simultaneously or sequentially. Bonding processes can be soldering or pressure-assisted sintering.

The coolant casing 9 (which is embodied as a cooling bath 9 in FIG. 8) is then mounted to the loop-shaped baseplate 7 using mounting screws 12 in the same manner as for traditional designs shown in FIG. 4. Therefore, the coolant casing 9 is mechanically and electrically coupled to the conductive track 16. With reference to FIG. 8, there are gaps between the heat exchanger 8/the central conductive track 17 and the baseplate 7/the coolant casing 9 along the horizontal X direction. There are also gaps between the heat exchanger 8 and the coolant casing 9 along the vertical Z direction. The gaps are in fluid communication to one another and collectively form a coolant reservoir 11. While it is not shown in FIG. 8, it would be understood that the coolant casing 9 comprises a coolant inlet and a coolant outlet each in flow communication with the coolant reservoir 11. In use, coolant enters into and circulates within the coolant reservoir 11 before existing the coolant reservoir 11, so as to take away heat generated by the high-side and low-side power switches 1100, 1200 mounted on the substrate 50. A sealing gasket 10 is used to prevent escape of coolant from the coolant reservoir 11.

In a final application assembly, the coolant casing 9 is grounded. Because the baseplate 7 and the conductive track 16 are made of electrically conductive material (e.g., metal), the baseplate 7 and the conductive track 16 are also grounded. The central conductive track 17 and the heat exchanger 8 remain at a floating potential, isolated from the grounded coolant casing 9 by coolant in the coolant reservoir 11. The coolant is a dielectric fluid, typically based on deionised water.

In this arrangement, the AC pad 4 is only capacitively coupled to the floating conductive track 17, and is not capacitively coupled to ground 20. The parasitic capacitance between the AC pad 4 and the conductive track 17 is illustrated using a capacitor 15 in FIG. 8. Therefore, no leakage path from the AC pad 4 to ground 20 exists in the assembly 1. In other words, the parasitic capacitance C_{AC} between the AC pad 4 to ground 20 is significantly reduced to a very low level, thereby preventing the generation of displacement currents and common mode noise during switching events.

Regarding the DC+ pad 2, only its region 18 is capacitively coupled to ground 20. A majority area of the DC+ pad 2 is only capacitively coupled to the floating conductive track 17. The parasitic capacitance between the region 18 and the conductive track 16 (grounded) is illustrated using a capacitor 30 (C_{DC+}) in FIG. 8. The parasitic capacitance between the majority area of the DC+pad 2 and the conductive track 17 (floating) is illustrated using a capacitor 13 in FIG. 8. The value of the capacitor 30 is much smaller than that of the capacitor 13, because of the small area of the region 18. Regarding the DC− pad 3, only its region 19 is capacitively coupled to ground 20. A majority area of the DC− pad 3 is only capacitively coupled to the floating conductive track 17, not ground 20. The parasitic capacitance between the region 19 and the conductive track 16 (grounded) is illustrated using a capacitor 32 (C_{DC-}) in FIG. 8. The parasitic capacitance between the majority area of the DC− pad 3 and the conductive track 17 (floating) is illustrated using a capacitor 14 in FIG. 8. The value of the capacitor 32 is much smaller than that of the capacitor 14, because of the small area of the region 19.

Therefore, capacitive coupling to ground 20 only occurs between the regions 18, 19 of the DC+, DC− pads 2, 3 that overlap the loop-shaped conductive track 16. For a given thickness of the electrically insulating body 5, the parasitic capacitances C_{DC+}, C_{DC-} can be adjusted by varying the size of the regions 18 and 19. Most preferably, regions 18 and 19 have the same area on the electrically insulating body 5. This allows C_{DC+}, C_{DC-} to be equalised, thereby reducing differential mode noise (which is a cause of EMI) during switching events. In practice, the region 18 may have an area that is within a range of between 80% and 120% of the area of the region 19.

In power electronic circuits, such as inverters, power semiconductor devices (e.g., the high-side and low-side switches 1100, 1200) are typically a source of EMI. The magnitude of EMI is proportional to switching speed, so EMI is a growing concern as applications switch from silicon to WBG power semiconductors, which have increased switching speeds. It is also heavily affected by parasitic capacitances C_{AC}, C_{DC+}, C_{DC-} as described above. Mitigation of conducted EMI is typically realised through filter circuitry. These measures increase the cost and size of electronic equipment, which is undesirable for users. In contrast, the power semiconductor module of the assembly 1 uses a substrate 50 with particularly designed layout of conductive pads that optimise the parasitic capacitances C_{AC}, C_{DC+}, C_{DC-} to minimise conducted EMI, and therefore reduces the need for additional filter circuitry.

Further, the assembly 1 suffers no loss in cooling efficiency as compared to the conventional assembly 100. Unlike known techniques for decoupling the AC pad and ground, the assembly 1 does not add any extra layer/structure to the thermal path between the substrate and the coolant along the Z direction.

The conductive tracks 4 and 16 may be referred to as “first conductive track” and “second conductive track” of the substrate 50, respectively. The conductive tracks 2 and 3 may be referred to as “third conductive track” and “fourth conductive track” of the substrate 50, respectively. The conductive track 17 may be referred to as a “fifth conductive track” of the substrate 50.

FIGS. 9 to 13 schematically illustrate power semiconductor assemblies 1A to 1E according to second to sixth embodiments of the present disclosure. Elements of the assemblies 1A to 1E that are identical to those of the assembly 1 are identified using the same labels. Elements of the assemblies 1A to 1E that correspond to, but are different from those of the assembly 1 are labelled using the same numerals but with a letter ‘A’ to ‘E’ for differentiation. The features and advantages described above with reference to the first embodiment are generally applicable to the second to sixth embodiments.

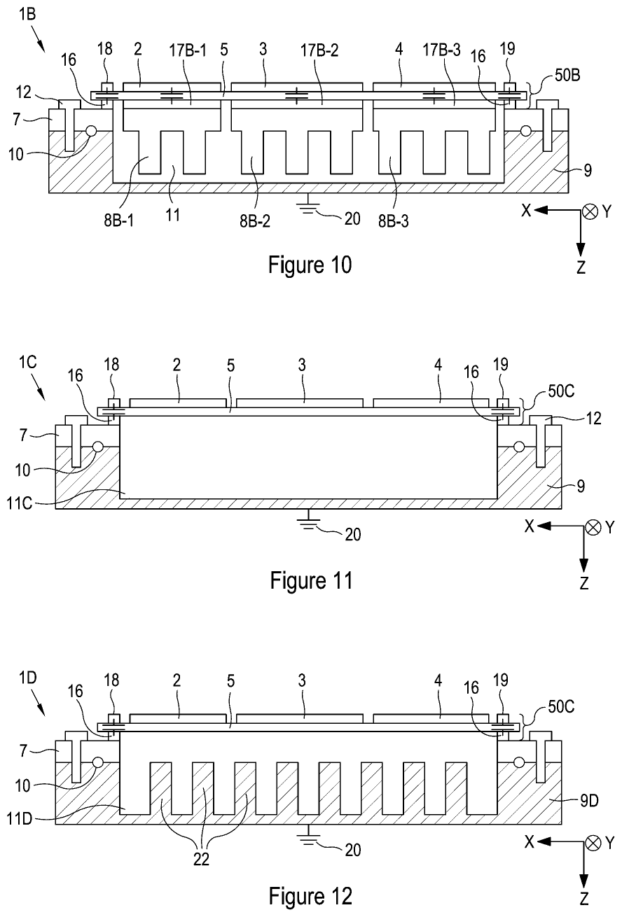

The assembly 1A differs from the assembly 1 in the cooling system. Within the assembly 1A, the coolant casing 9A is bonded directly to the conductive track 16, without the intermediate steps of bonding the conductive track 16 to a baseplate and mounting the coolant casing to the baseplate with screws and a sealing gasket. The bonding may be by sintering, soldering or conductive epoxy resin. This design enables the footprint of the assembly 1A to be reduced as compared to the assembly 1, thereby saving space in an end-user's application. This is of particular importance in space-limited applications such as automotive. The design of the assembly 1A also enables cost reduction through reduction of components and process steps. Sealing integrity of the coolant reservoir 11 is also improved, as there is no reliance on any sealing gasket. The assembly 1B differs from the assembly 1 in both the power semiconductor module and the cooling system. In particular, the substrate 50B of the power semiconductor module includes multiple conductive tracks 17B-1, 17B-2, 17B-3 within its bottom electrically conductive layer that are surrounded by the loop-shaped conductive track 16. The conductive tracks 17B-3, 17B-1, 17B-2 may be referred to as “sixth conductive track”, “seventh conductive track”, and “eighth conductive track” of the substrate, respectively. Three heat exchangers 8B-1, 8B-2, 8B-3 are then bonded to the conductive tracks 17B-1, 17B-2, 17B-3, respectively. As shown in FIG. 10, the conductive track 17B-1 and the heat exchanger 8B-1 overlap with only the conductive track 2 of the top patterned electrically conductive layer; the conductive track 17B-2 and the heat exchanger 8B-2 overlap with only the conductive track 3 of the top patterned electrically conductive layer; and the conductive track 17B-3 and the heat exchanger 8B-3 overlap with only the conductive track 4 of the top patterned electrically conductive layer. In other words, the single continuous conductive track 17 within the bottom electrically conductive layer of the substrate 50 and the single heat exchanger 8 of the assembly 1 are now divided into multiple parts of the assembly 1B which match the conductive tracks 2, 3, 4 on the top surface of the electrically insulating body 5, respectively.

Because the conductive tracks 2, 3, 4 are typically connected to different voltage potentials in use, the assembly 1B is useful for preventing crosstalk between the conductive tracks 2, 3, 4 through the floating heat exchangers. The heat exchangers 8B-1, 8B-2, 8B-3 can be concentrated in areas with the greatest heat flux, potentially reducing material usage and cost. The reduction of the area of each heat exchanger also enables a wider range of bonding processes to be used, since some processes are area-limited, such as pressureless sintering. It would be understood that each pair of a conductive track and a heat exchanger (e.g., 17B-1 and 8B-1) can be further divided into multiple parts.

The assembly 1C differs from the assembly 1 in both the power semiconductor module and the cooling system. In particular, the substrate 50C of the power semiconductor module does not have the large-area central conductive track 17 within its bottom electrically conductive layer, and the cooling system of the assembly 1C does not use any heat exchanger 8 bonded to the central conductive track 17. Therefore, within the assembly 1C, coolant in the coolant reservoir 11 contacts the bottom surface of the electrically insulating body 5 directly. This arrangement is useful for reducing the thermal resistance from the electrically insulating body 5 to the coolant.

The assembly 1D differs from the assembly 1C in the cooling system. In particular, the coolant casing 9D of the assembly 1D incorporates a structure 22 to guide the path of coolant within the coolant casing 9D for optimised cooling of the substrate 50. The structure 22 is formed on an internal surface of the coolant casing 9D, and comprises protrusions with flow channels there-between.

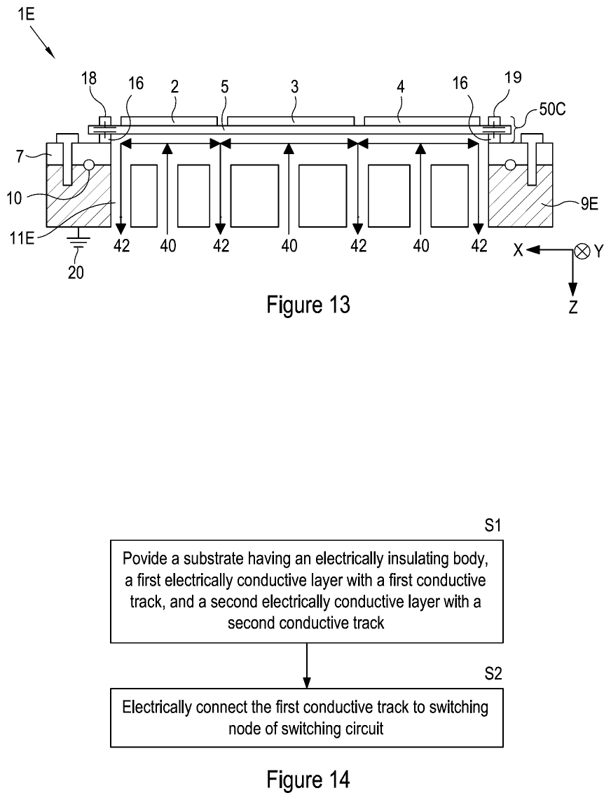

The assembly 1E also differs from the assembly 1C in the cooling system. The coolant casing 9E of the assembly 1E is part of a jet impingement cooling system, in which jets of cooling fluid 40 are directed at the bottom surface of the electrically insulating body 5 in areas requiring cooling. The direction of flow of the liquid coolant in indicated by arrows in FIG. 13. While it is not shown in FIG. 13, it would be understood that the coolant casing 9E comprises a coolant inlet through which coolant flows into the coolant reservoir 11E surrounded by the coolant casing 9E, and a coolant outlet through which coolant leaves the coolant reservoir 11E. The jet impingement cooling system would also include a structure (e.g., arranged within the coolant reservoir 11E) in fluid communication with the coolant inlet for generating the jets of cooling fluid 40, and a structure (e.g., arranged within the coolant reservoir 11E) in fluid communication with the coolant outlet for collecting the returned jets of cooling fluid 42.

While the assemblies 1, 1A-1E or their power semiconductor modules described above are for realising the particular half-bridge circuit structure 1000 of FIG. 1, it would be understood that the assemblies 1, 1A-1E can be used to realise any type of switching circuit which has high-side and low-side power semiconductor devices, and a switching node therebetween, and the switching circuit is in no way limited to a half-bridge circuit structure. For example, the switching circuit may be one or more phases of a three-level neutral point clamped inverter, and each of high-side and low-side power semiconductor devices may comprise two power semiconductor devices connected in series.

Further, in each of the assemblies 1, 1A-1E, the power semiconductor module comprises a single substrate 50, and the top patterned electrically conductive layer of the single substrate 50 comprises a DC+ pad 2, DC− pad 3, and an AC pad 4. It would be appreciated that the power semiconductor modules can be modified such that it uses more than one substrate (e.g., to achieve double-sided cooling), and that the DC+, DC− and AC pads 2, 3, 4 can be formed on one or more of the substrates. In other words, the substrate that has the AC pad may not have one or both of the DC+ and DC− pads. In addition, it is known that the high-side and low-side power semiconductor devices of a switching circuit typically include control electrodes (e.g., gate electrodes) for switching on/off a power current flowing through the devices, and that, accordingly, the substrate(s) of the power semiconductor modules would include corresponding control pads for electrically connection with the control electrodes. The control pads are not shown in any of the figures, but it would be understood that they may be formed on the surface of the substrate(s) that face the switching circuit.

Further, it would be appreciated that the power semiconductor modules of the assemblies 1, 1A-1E may be used with different types of cooling systems, which are not limited to the exemplary cooling systems shown in FIGS. 8 to 13.

It would be further understood that the conductive track 16 may have any suitable shape which is not limited to the rectangular shape as shown in FIG. 6. For example, the conductive track 16 may assume a loop shape that is oval, annular, square, polygonal or non-geometrical, etc., as long as it forms a closed loop that is without a gap.

FIG. 14 schematically illustrates processing steps of a method for manufacturing a power semiconductor module (e.g., the module within any of the assemblies 1, 1A-1E). The power semiconductor module has a switching circuit comprising: high-side and low-side power semiconductor devices (e.g., power switches 1100, 1200), and a switching node (e.g., ‘AC’ node) between the high-side and low-side power semiconductor devices.

At step S1, a substrate (e.g., the substrate 50, 50B or 50C) is provided. The substrate comprises: an electrically insulating body (e.g., the body 5); a first electrically conductive layer arranged on a first surface (e.g., the top surface) of the electrically insulating body that faces the switching circuit; and a second electrically conductive layer arranged on a second opposite surface (e.g., the bottom surface) of the electrically insulating body. The first electrically conductive layer comprises a first conductive track (e.g., the conductive track 4) and the second electrically conductive layer comprises a second conductive track (e.g., the conductive track 16) for coupling to a heat removal structure (e.g., the coolant casing 9, 9A, 9D or 9E).

At step S2, the first conductive track is electrically connected to the switching node of the switching circuit. This may be done using any suitable connection techniques (e.g., direct bonding, wire bonds, and/or copper clips etc.), depending upon the particular configuration of the switching circuit as well as the locations of the power electrodes within high-side and low-side power semiconductor devices. The first conductive track does not overlap with the second conductive track across the electrically insulating body.

To manufacture a power semiconductor assembly (e.g., any of the assemblies 1, 1A-1E), the following processing steps may be performed in addition to steps S1 and S2.

At step S3, a heat removal structure (e.g., the coolant casing 9, 9A, 9D, 9E) is mounted/coupled (directly or via another structure) to the second conductive track.

Within the assembly, all joints are made by a suitable technology, which may include sintering, soldering or bonding by conductive epoxy resin.

The terms “having”, “containing”, “including”, “comprising” and the like are open and the terms indicate the presence of stated structures, elements or features but not preclude the presence of additional elements or features. The articles “a”, “an” and “the” are intended to include the plural as well as the singular, unless the context clearly indicates otherwise.

The skilled person will understand that in the preceding description and appended claims, positional terms such as ‘top’, ‘bottom’, ‘lateral’, ‘vertical’, etc. are made with reference to conceptual illustrations of a power semiconductor module/assembly, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1. A power semiconductor module, comprising:
a switching circuit comprising high-side and low-side power semiconductor devices, and a switching node between the high-side and low-side power semiconductor devices; and
a substrate comprising: an electrically insulating body; a first electrically conductive layer arranged on a first surface of the electrically insulating body that faces the switching circuit; and
a second electrically conductive layer arranged on a second opposite surface of the electrically insulating body;
wherein the first electrically conductive layer comprises a first conductive track electrically connected to the switching node, and the second electrically conductive layer comprises a second conductive track for coupling to a heat removal structure, and wherein the first conductive track does not overlap with the second conductive track across the electrically insulating body.

2. The power semiconductor module of claim 1, wherein the second conductive track is loop-shaped.

3. The power semiconductor module of claim 1, wherein the first electrically conductive layer further comprises third and fourth conductive tracks which are electrically connected a DC positive node and a DC negative node of the switching circuit, and wherein each of the third and fourth conductive tracks overlaps with the second conductive track across the electrically insulating body.

4. The power semiconductor module of claim 3, wherein an overlapping area between the third and second conductive tracks across the electrically insulating body has a substantially identical size to an overlapping area between the fourth and second conductive tracks across the electrically insulating body.

5. The power semiconductor module of claim 1, wherein the second electrically conductive layer further comprises a fifth conductive track for coupling to a heat exchanger, wherein the fifth conductive track is surrounded by and spaced apart from the second conductive track.

6. The power semiconductor module of claim 5, wherein the first conductive track overlaps with the fifth conductive track across the electrically insulating body.

7. The power semiconductor module of claim 3, wherein:
the second electrically conductive layer further comprises sixth to eighth conductive tracks for coupling to a plurality of heat exchangers, wherein the sixth to eighth conductive tracks are surrounded by the second conductive track, the sixth to eighth conductive tracks being spaced apart from the second conductive track and also spaced apart from one another;
the sixth conductive track overlaps with only the first conductive track of the first electrically conductive layer across the electrically insulating body;
the seventh conductive track overlaps with only the third conductive track of the first electrically conductive layer across the electrically insulating body; and
the eighth conductive track overlaps with only the fourth conductive track of the first electrically conductive layer across the electrically insulating body.

8. The power semiconductor module of claim 1, wherein at least one of the high-side and low-side power semiconductor devices comprises a wide bandgap power semiconductor device.

9. A power semiconductor assembly, comprising:
the power semiconductor module of claim 1; and
a coolant casing for containing coolant, wherein the coolant casing is coupled to the second conductive track so that the second conductive track shares a voltage potential of the coolant casing, and wherein the heat removal structure comprises the coolant casing.

10. The power semiconductor assembly of claim 9, further comprising a baseplate bonded between the second conductive track and the coolant casing.

11. The power semiconductor assembly of claim 9, wherein the coolant casing is directly bonded to the second conductive track.

12. The power semiconductor assembly of claim 9, further comprising a coolant contained in the coolant casing, wherein the coolant is thermally coupled to the electrically insulating body.

13. The power semiconductor assembly of claim 12, wherein the coolant is dielectric.

14. The power semiconductor assembly of claim 12, wherein the coolant contacts the second surface of the electrically insulating body directly.

15. The power semiconductor assembly of claim 14, wherein an internal surface of the coolant casing comprises a structure for guiding the coolant.

16. The power semiconductor assembly of claim 9, wherein the coolant casing is part of a jet impingement cooling system which is configured to direct jets of coolants onto the substrate.

17. The power semiconductor assembly of claim 9, wherein the second electrically conductive layer of the power semiconductor module further comprises a fifth conductive track surrounded by and spaced apart from the second conductive track; and
the power semiconductor assembly further comprising a heat exchanger bonded to the fifth conductive track, wherein the heat exchanger is electrically insulated from the second conductive track.

18. The power semiconductor assembly of claim 9, wherein:
the first electrically conductive layer further comprises third and fourth conductive tracks which are electrically connected a DC positive node and a DC negative node of the switching circuit, and wherein each of the third and fourth conductive tracks overlaps with the second conductive track across the electrically insulating body;
the second electrically conductive layer further comprises sixth to eighth conductive tracks surrounded by the second conductive track, the sixth to eighth conductive tracks being spaced apart from the second conductive track and also spaced apart from one another;
the sixth conductive track overlaps with only the first conductive track of the first electrically conductive layer across the electrically insulating body;
the seventh conductive track overlaps with only the third conductive track of the first electrically conductive layer across the electrically insulating body;
the eighth conductive track overlaps with only the fourth conductive track of the first electrically conductive layer across the electrically insulating body; and
the power semiconductor assembly further comprising a plurality of heat exchangers, each of which is bonded to a respective one of the sixth to eighth conductive tracks and is electrically insulated from the second conductive track.

19. A method of manufacturing a power semiconductor module, the power semiconductor module having a switching circuit comprising: high-side and low-side power semiconductor devices, and a switching node between the high-side and low-side power semiconductor devices, the method comprising:
providing a substrate which comprises: an electrically insulating body; a first electrically conductive layer arranged on a first surface of the electrically insulating body that faces the switching circuit; and a second electrically conductive layer arranged on a second opposite surface of the electrically insulating body, wherein the first electrically conductive layer comprises a first conductive track and the second electrically conductive layer comprises a second conductive track for coupling to a heat removal structure; and
electrically connecting the first conductive track to the switching node of the switching circuit;
wherein the first conductive track does not overlap with the second conductive track across the electrically insulating body.

20. A method of manufacturing a power semiconductor assembly, comprising:
the method of claim 19; and
coupling a heat removal structure to the second conductive track.
